(19) United States
(12) Patent Application Publication
(10) Pub. No.: US 2005/0110018 A1
(43) Pub. Date: May 26, 2005

(54) Display device with picture decoding

(76) Inventors: Renatus Josephus Van Der Vleuten, Eindhoven (NL); Mark Thomas Johnson, Eindhoven (NL); Herbert Lifka, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/501,687

(22) PCT Filed: Dec. 12, 2002
(86) PCT No.: PCT/IB02/05415

(30) Foreign Application Priority Data
Jan. 18, 2002 (EP) 02075213.5

(51) Int. Cl. H01L 29/04

(52) U.S. Cl. 257/72

(57) ABSTRACT

ICs or separate semiconductor areas are provided on a carrier e.g. in a bus structure or at the crossing of rows and columns. The separate semiconductor areas contain electronics (address of pixel in memory, identification) to drive groups of pixels and to provide a distributed information decoding (MPEG, JPEG etc.) and subsequently drive the pixels dependent on the decoded information. A controller may further determine whether data is supplied, dependent on successive frames of information

The invention relates to a display device comprising a substrate, which is provided with groups of pixels and at least one semiconductor device associated with each group of pixels and being provided at the area of said group of pixels.

Examples of such active matrix display devices are TFT-LCDs or AM-LCDs, which are used in laptop computers and in organizers, but also find an increasingly wider application in GSM telephones. Instead of LCDs, for example, (polymer) LED display devices may also be used.

A general problem in these types of display devices is the fact that the provision of extra electronics at the area of the pixels is at the expense of the aperture. The electronics may be realized on the substrate in polycrystalline silicon. Manufacturing tolerances and interconnections however generally limit the electronics at the area of the pixels to simple functions. So electronics in polysilicon remains restricted to peripheral circuitry.

The invention however provides a display device, in which the semiconductor device at the area of said group of pixels is provided with drive means for driving the pixels dependent on data to be displayed and with data processing means.

Preferably the semiconductor devices are provided with means for recognizing the location of the group of pixels.

For example, an 8-bit bus configuration is possible now through which the address information and the picture information are consecutively passed. In this case, by sending encoded data via the bus structure a lower frequency may be used for driving the display device, which reduces the dissipation. This is possible because the semiconductor devices (ICs) can comprise drive electronics at the area of the pixels. This provides the possibility to provide for instance a decoding function within each group of pixels.

It is possible to provide the ICs at a defined position (within a group of pixels) by providing a semiconductor substrate with a plurality of semiconductor devices having electric connection contacts on their surface. The semiconductor devices are mutually separated in a surface region of an original semiconductor substrate, and the electric connection contacts are connected to a conductor pattern of the display in an electrically conducting manner. The semiconductor devices are then separated from the semiconductor substrate.

Since the location of an IC to be provided is known in advance, it can be provided in advance (during IC processing (ROM structure) or via e-PROM techniques), for example, with an address register or with one or more data registers. The address is provided in the data, sent over the bus and is recognized by certain ICs (and associated (groups) of pixels) and picture information in an encoded form is stored. Thereafter, the picture information is decoded and corresponding voltages are supplied to pixels, if necessary dependent on possible further commands. So the device provides, as it were, a kind of “distributed decoding”.

Notably, but not exclusively, when using monocrystalline silicon, it is possible (as mentioned above) to realize complete functions allowing a different type of architecture of the display device than the architecture used in conventional matrix structure, for example, a bus structure. Since the ICs are manufactured in advance, more extensive electronic functions than in the conventional polysilicon technology can be realized, although the invention does not preclude the realization of the encoding functions in polysilicon technology. Consequently in the context of this patent (application) the term “semiconductor devices” also comprises separate polysilicon areas.

Especially when using ICs as the semiconductor devices, since these are situated with respect to each other in exactly the same way as on the semiconductor substrate during their fixation to the substrate, these ICs are provided at a very accurate pitch. This may be a constant pitch in one direction such as in matrix-shaped configurations of the pixels. The pitch may alternatively be variable.

Moreover, the semiconductor devices (ICs) are realized in a semiconductor layer whose thickness is typically 0.2 micrometer. The result is that these semiconductor devices in the finished display device have a negligible thickness (less than 1 micrometer). In, for example, display devices based on thickness-sensitive effects such as the STN effect, this is so small with respect to the effective thickness of the liquid layer that said effects do not occur, not even in the presence of a spacer at the location of an IC.

The article “Flexible Displays with Fully Integrated Electronics”, SID Int. Display Conf., September 2000, pp. 415 to 418 describes a process in which specifically formed semiconductor devices in a liquid suspension are passed across a substrate and reach correspondingly formed “apertures” or indentations in the substrate. The semiconductor devices (usually ICs which are manufactured via standard techniques) are arbitrarily distributed across the indentations in the substrate. After the ICs have been provided, connections with pixels are established.

Since the exact position of such an IC is not known in advance now, it must be fixed in a special way when using a bus structure, for example, by means of (an optical sensor and) a programmable memory so that this address information can be programmed with, for example, a laser beam.

The “distributed decoding” has different applications. Since in fact coded information is now written into the local memories of the semiconductor devices, all advantages of source coding and channel coding, as known from digital transmission (audio, video, data transmission) extend as far as these semiconductor devices. This on the other hand simplifies or partly replaces driving electronics as used in conventional displays.

In one embodiment the addressing rate of the semiconductor devices is variable for instance if the driving means comprise a frame memory and means to detect changes between the contents of subsequent frames. On the other hand said detection may take place in further driving means for the display, such as e.g. a microprocessor or other driving circuit, which provides addresses and data to said bus circuitry. In a further embodiment encoded data to be displayed is transported to at least a group of the semiconductor devices at full frame rate after detecting a certain amount of change between the contents of subsequent frames or of subsequent subframes.

These and other aspects of the invention are apparent from and will be elucidated with reference to the embodiments described hereinafter.

In the drawings:

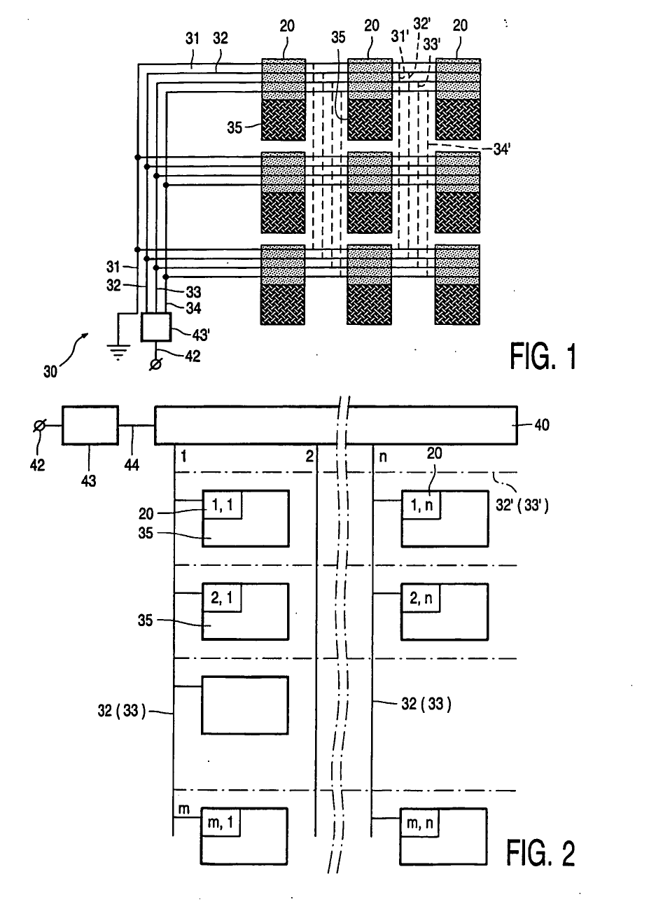

FIG. 1 is an electrical equivalent of a possible embodiment of a display device according to the invention,

FIG. 2 is an electrical equivalent of another embodiment of a display device according to the invention,

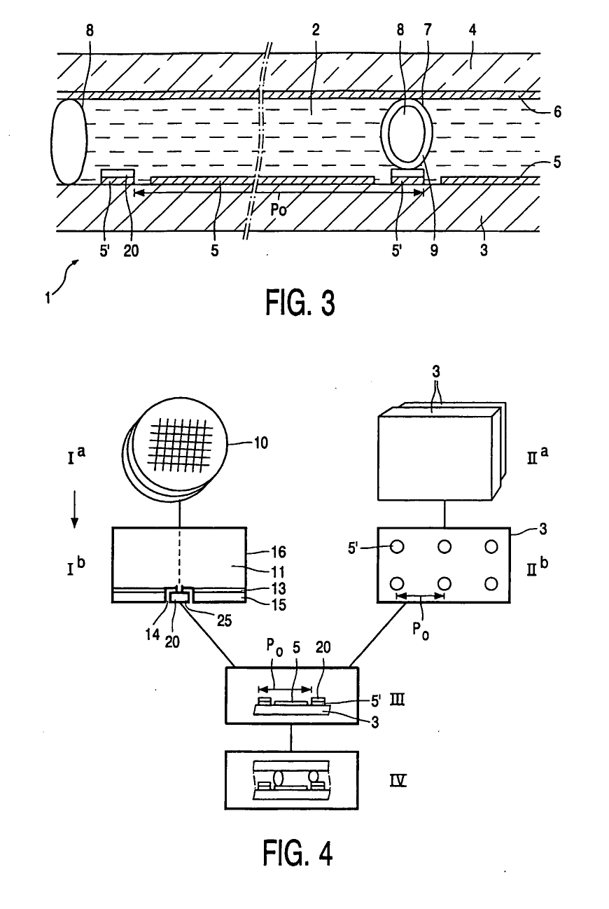

FIG. 3 is a diagrammatic cross-section of a part of a display device according to the invention,

FIG. 4 is a flow chart of a method of manufacturing a display device according to the invention,

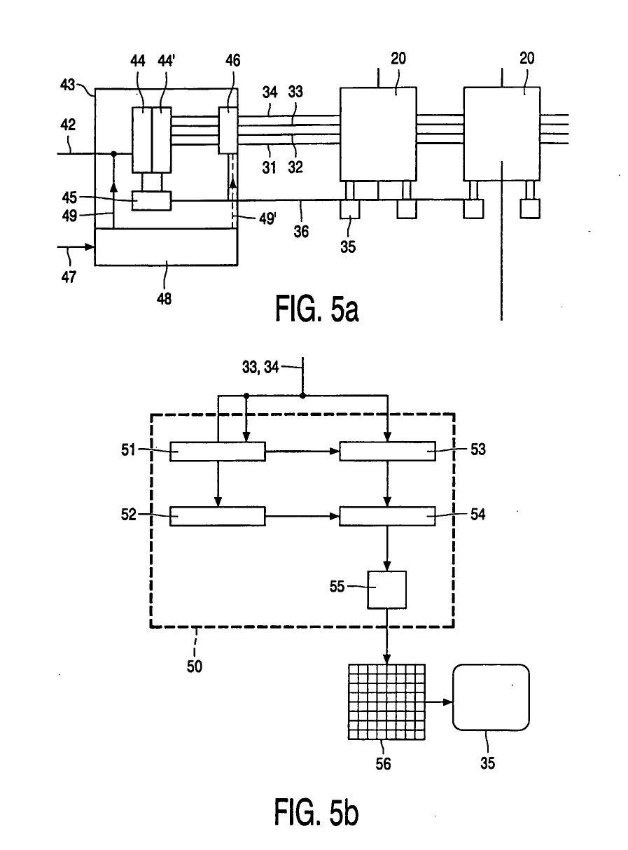

FIG. 5 diagrammatically shows a method of encoding, while

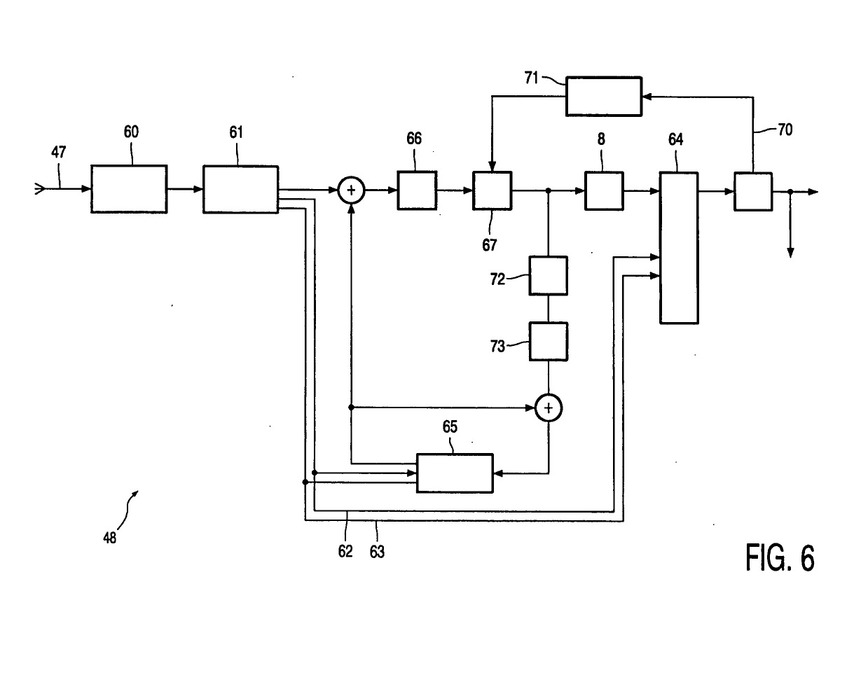

FIG. 6 diagrammatically shows another method of encoding

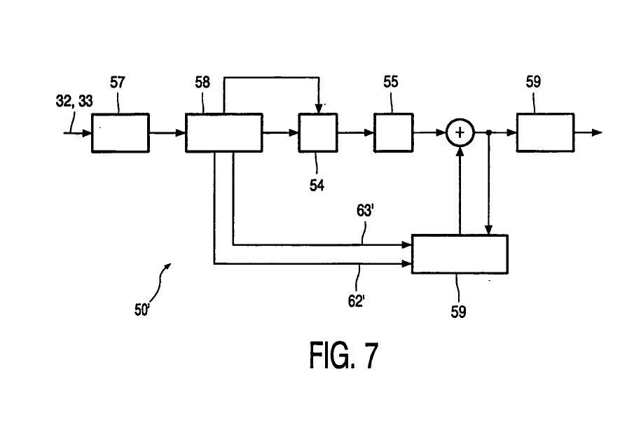

FIG. 7 diagrammatically shows a method of decoding

The Figures are diagrammatic and not drawn to scale. Corresponding elements are generally denoted by the same reference numerals.

FIG. 1 shows diagrammatically an equivalent of a display device 30 having a bus structure. ICs (semiconductor devices) 20 are connected to a power supply voltage via connection lines 31, 32 (in this example, line 31 is connected to earth), while the lines 33, 34 (serially) supply information and, for example, a clock signal. The information after passing a processor 43, is structured, for example in such a way that the first bits comprise the address information and the last bits comprise the information about the picture contents. Although only two lines 33, 34 are shown, they form, in this example, an 8-bit bus through which the address information and the picture information are consecutively passed. Alternatively information may be superimposed on the power supply lines 31, 32 or it may be provided via a single line (serial bus). Since, as will be further described, the location of an IC is known or not known in advance, it may be provided with a fixed address by an address register and one or more data registers. For given ICs (and associated (groups) of pixels 35), the address is recognized by the ICs and picture information is stored, whereafter it is applied to the pixels 35, dependent on commands also to be given through the lines 33, 34.

The bus structure may be formed as a mesh structure (denoted by broken lines 31′, 32′, 33′, 34′ in FIG. 1) so that the resistance is decreased (and hence again the dissipation).

Other functions may also be accommodated in the IC. For example, a part of the display device may be blocked for changes of information by means of a command register built in the IC, or may be used for storing the information in the IC for a part of the display device, which information is only displayed at command (so-called “private mode”). Various algorithms for picture processing (for example, gamma correction) or driving may also be realized in the ICs.

FIG. 2 is an electric equivalent of another display device 30 to which the invention is applicable. FIG. 2 shows a plurality of pixels arranged or not arranged in groups 35 in a matrix structure. In the display device, each group 35 comprises the means for recognizing the location, for example, a command register (not shown). The command registers are in turn programmed with a given address and recognize the associated address information as described with reference to FIG. 1, when this information is presented on the bus lines 32 (33). The semiconductor device may also comprise a flip-flop in which, dependent on the state of this flip-flop, information is displayed again (“private mode”). The bus electrodes are provided with data, commands, etc. via, for example, a drive circuit 40. If necessary, incoming data signals 42 first pass a processor 43. Mutual synchronization takes place via drive lines 44. Since the data, commands and other signals are now presented via a divided bus structure to the groups 35, this consumes less power (the data, commands, etc. are presented at a lower frequency). If necessary, a mesh structure may also be used again in this case.

In the relevant example, the pixels form part of a liquid crystal display device, but (O)LED display devices are alternatively possible, as well as display elements based on other effects (electrophoretic, electrochromic or micromechanical effects, switching mirror devices, foil displays or field emission displays).

FIG. 3 is a diagrammatic cross-section of a part of a light-modulating cell 1 with a liquid crystal material 2 which is present between two substrates 3, 4 of, for example, glass or synthetic material, provided with (ITO or metal) electrodes 5, 6. Together with an intermediate electro-optical layer, parts of the electrode patterns define pixels. If necessary, the display device comprises orientation layers (not shown) which orient the liquid crystal material on the inner walls of the substrates. The liquid crystal material may be a (twisted) nematic material having, for example, a positive optical anisotropy and a positive dielectric anisotropy, but may also make use of a bistable effect such as the STN effect, or the chiral nematic effect, or the PDLC effect. The substrates 3, 4 are customarily spaced apart by spacers 7, while the cell is sealed with a sealing rim 8 which is customarily provided with a filling aperture. A typical thickness of the layer of liquid crystal material 2 is, for example, 5 micrometers. The electrodes 5, 5′ have a typical thickness of 0.2 micrometer, while also the thickness of the semiconductor devices (ICs) 20 is about 0.2 micrometer in this example. In FIG. 3, a spacer 7 is shown at the location of an electrode 5′ and IC 20. The overall thickness of electrode and IC 20 is substantially negligible as compared with the thickness of the layer of liquid crystal material 2. The presence of the spacer 7 does not have any influence, or hardly has any influence, on the opto-electrical properties of the display device, notably when spacers with a hard core 8 and an elastic envelope 9 having a thickness of about 0.2 micrometer are chosen. If necessary thicker IC's can be used which also function as spacer (or a through metallization may even be realized). The other side of the IC may then have one or more contacts, which provide connections (for electrical signals) to the other substrate.

For manufacturing the semiconductor devices (transistors or ICs) 20, in this example use is made of conventional techniques. The starting material is a semiconductor wafer 10 (see FIG. 4, step I^{a}, FIG. 3), preferably silicon, with a p-type substrate 11 on which an n-type epitaxial layer 15 having a weak doping (10¹⁴ atoms/cm³) is grown. Prior to this step, a more heavily doped n-type layer 13 (doping about 10¹⁷ atoms/cm³) is provided by means of epitaxial growth or diffusion. Further process steps (implantation, diffusion, etc.) realize transistors, electronic circuits or other functional units in the epitaxial layer 15. After completion, the surface is coated with an insulating layer such as silicon oxide. Contact metallizations are provided via contact apertures in the insulating layer by means of techniques that are customary in the semiconductor technology.

In a variant in which the transistors, electronic circuits or other functional units are realized in the SOI technology in which a thin surface area is embedded in an insulating layer, contact metallizations may be directly provided on contact regions of the transistors of the semiconductor devices.

Subsequently, the n-type regions 14 are subjected via a mask to an etching treatment with HF (under the influence of an electric field). In this treatment, the heavily doped n-type region 14 is isotropically etched, as well as the underlying n-type epitaxial layer 13. The weakly doped n-type epitaxial layer 15 is, however, etched anisotropically so that, after a given period, only a small region 25 remains in this layer (see FIG. 4, step I^{b}).

The transistors, electronic circuits (ICs) or other functional units are, however, still at their originally defined position. A regular pattern of such units will generally be manufactured at a fixed pitch.

Prior to, simultaneously with or after this treatment, substrates 3 of the display device are provided with metallization patterns which (also at defined positions) will comprise one or more electrodes 5′ (FIG. 4, steps II^{a}, II^{b}). In this example, the parts 5′ of the metallization patterns on the substrate 3 are ordered similarly (the same pitch in different directions) as the electronic circuits (ICs) 20 in the semiconductor wafer 10.

In a subsequent step, the semiconductor wafer 10 is turned upside down, in which the metallization patterns 5′ on the substrate 3 are accurately aligned with respect to the electronic circuits (ICs) 20 in the semiconductor wafer 10, whereafter electrical contact is realized between metallization patterns 5′ and contact metallizations. To this end, use is made of, for example, a conducting glue or anisotropically conducting contacts on the electrodes 5′. The electronic circuits (ICs) 20 are detached from the semiconductor wafer 10 by means of vibration or by a different method. A substrate 3 is then obtained which is provided with picture electrodes 5 and ICs 20 which are very accurately aligned both with respect to the picture electrodes 5 and with respect to each other (step III in FIG. 4). Moreover, the reduction of aperture is exclusively determined by the dimension of the ICs (or transistors).

The display device 1 is subsequently completed in a customary manner, if necessary, by providing orientation layers, which orient the liquid crystal material on the inner walls of the substrate. Spacers 7 are customarily provided between the substrates 3, 4, as well as a sealing rim 8, which is customarily provided with a filling aperture, whereafter the device is filled with LC material in this example (step IV in FIG. 4).

Since the semiconductor devices (ICs) 20 are made in advance, more extensive electronic functions can be realized therein than in the conventional polysilicon technology. Notably when using monocrystalline silicon or recrystallized polysilicon, it is possible to realize functions with which a different type of architecture of the display device can be made possible than with the conventional matrix structure.

For instance, if incoming data signals 42 (FIG. 5a) are provided in a compressed form according to international standards (e.g. JPEG, MPEG) these data signals are distributed to the ICs (semiconductor devices) 20 via connection lines (bus lines) 31, 32 33, 34.

Encoded data, which generally is obtained (JPEG) via a Discrete Cosine Transformation for blocks of 8×8 pixels, is made up of blocks of 8×8 matrices, whereas for further encoding quantization, zig-zag scan, run length coding (RLC) and variable length coding (Huffman coding, VLC) is generally used. Encoded signals, obtained via lines 33, 34 is decoded in the ICs (semiconductor devices) 20. To this end the ICs (semiconductor devices) 20 in this example each comprise a (JPEG) decoder 50 (FIG. 5b). A typical decoder as shown here contains a variable length coding (VLC) table 51 and a quantization table 52. Together with a VLC+RLC decoder 53, a de-quantizer 54 and an inverse Discrete Cosine Transformation block 55 these elements decode the bus-information into the correct luminance values, which are written into a memory device 56 for a block of 8×8 pixels. Via suitable electronics such as D-A converters, counters and registers in electronic block (IC) 20 (not shown in FIG. 5b) pixel electrodes in a group of 8×8 pixels are subsequently provided with the associated voltages.

Especially if still pictures are displayed there is little or no need to provide the ICs (semiconductor devices) 20 with new data and the transfer of data can be restricted to updating the contents of the memory device 56. To this end the processor 43 (FIG. 5a) comprises frame memories 44, 44′ in which the contents of subsequent frames of information are stored. The contents are compared in a comparator 45 and, dependent on the outcome, a buffer circuit 46 is enabled to provide the bus lines 33, 34 with fresh data. Also only subframes may be compared, e.g. in picture-in-picture applications. On the other hand the subframes (or combinations of subframes) which are compared may correspond with the pixel information associated with a certain electronic block (IC) 20 and the corresponding pixels in a group 35 of 8×8 pixels Dependent on the (change of) information the picture-in picture part may be addressed with an addressing rate different from the addressing rate for other parts.

If necessary comparison of the contents of subsequent (sub) frames may be incorporated in the electronic blocks (ICs) 20.

Apart from this the contents of the memory device 56 may be updated every n frames, n being a large number to prevent errors due to leakage in transistors. Such leakage may also be detected by monitoring current via an extra resistor and setting a flip-flop or generating a signal 36 from the ICs (semiconductor devices) 20 to the processor 43.

To display pictures, which are provided in non-encoded form the processor 43 (FIG. 5) in this example also comprises the possibility to encode such information (FIG. 6). This information may even be provided in an analogue form. In this case it is first digitized by a (not shown) AD-converter, before being encoded in the subdevice 48, which is shown in more detail in FIG. 6 in which for larger groups of pixels (e.g. 128×128 pixels or more) MPEG encoding is used. The subdevice 48, as an example of a device in which also the bit rate at the output is kept constant, comprises a picture reordering device 60 and a motion estimator 61, which determines a motion vector 62 allowing an area of a picture to be deduced from a previous picture. Together with the mode 63 used in the encoding function this motion vector 62 is provided to a multiplexer 64 and a (memory+predictor) function (block 65). The output of the memory predictor 65 is used to modify the output of the estimator 61, if necessary, whereafter a Discrete Cosine Transformation (block 66) quantization (block 67) and variable length coding (block 68) is generally used. The encoded data is subsequently provided via multiplexer 64 to a buffer circuit 68 if necessary. Several feedback loops may be incorporated in the device 48 such as, in this example, a feedback loop 69 comprising a bitrate regulation function 70 and a feedback loop 71 comprising an inverse quantization function (block 72) and an inverse Discrete Cosine Transformation (block 73).

After having been encoded as described above, the encoded data may be treated in a similar way as incoming data 42, indicate by numeral 49 or be transferred to buffer circuit 46, indicated by numeral 49′ (FIG. 5(a)).

The encoded signals, obtained via lines 32, 33 is decoded in the ICs (semiconductor devices) 20 again. To this end the ICs (semiconductor devices) 20 in this example each comprise a (MPEG) decoder 50′ which apart from a buffer circuit 57 (if necessary) and a demultiplexer and Variable Length Decoder 58 contains a de-quantizer 54 and an inverse Discrete Cosine Transformation block 55. In the Variable Length Decoder 58 a motion vector 62′ is deduced again from the information related a previous picture. Together with the mode 63′ used this motion vector 62 is provided to a multiplexer 64 and a memory predictor 65′. The output of the (memory+predictor)-function (block 59) is used to modify the output of the estimator 61, if necessary, whereafter picture reordering takes place (block 59).

For detailed information on different kinds of encoding and decoding reference is made to standard textbooks on digital communication technology, digital television and to International Standards such as MPEG, JPEG, JPEG 2000 etc. Encoding may also comprise data compression and encryption.

Since the distributed ICs (drivers, decoders) have a defined address different methods of updating the display information are possible. If necessary addressing of a first part of the display is interrupted to restart the addressing if important sections need to be updated. This will be demonstrated in the following examples.

### EXAMPLE 1

Rapidly changing incoming data 42 (e.g. a video signal) is presented. The processor 43 addresses all blocks 20 at full frame rate with compressed data.

### EXAMPLE 2

Incoming data 42 (e.g. a video signal) remains constant over several frames. The processor 43 addresses those blocks 20, where information to be displayed is constant (in one or more of the next following frames) with less compressed or even uncompressed data. This improves the picture quality. Preferably the data is compressed using a compression method that produces a scalable compression, such as described in WO 01/17268, which allows the image data to be successively refined, resulting in a lower bandwidth. A single bit can be used to indicate whether the data sent to a block contains update/refinement information of previous data or completely new data.

### EXAMPLE 3

In computer or control applications often only certain parts of a display need updating. In this example the processor 43 identifies the blocks where most information is changing and addresses these first with coded (or uncoded) data. Other blocks are only updated (with coded data) if bandwidth permits, but need only be updated once in several frames.

The protective scope of the invention is not limited to the embodiments described. As stated in the opening paragraph, the pixels may also be formed by (polymer) LEDs which may be provided separately or as one assembly, while the invention is also applicable to other display devices, for example, plasma displays, foil displays and display devices based on field emission, electro-optical or electromechanical effects (switchable mirrors).

Alternatively, as stated, flexible substrates (synthetic material) may be used (wearable displays, wearable electronics). Also the possibility of manufacturing, for example circular or elliptic display devices is not excluded.

The invention resides in each and every novel characteristic feature and each and every combination of characteristic features. Reference numerals in the claims do not limit their protective scope. Use of the verb “to comprise” and its conjugations does not exclude the presence of elements other than those stated in the claims. Use of the article “a” or “an” preceding an element does not exclude the presence of a plurality of such elements.

1. A display device comprising a substrate, which is provided with groups of pixels and at least one semiconductor device associated with each group of pixels and being provided at he area of said group of pixels, the semiconductor device being provided with drive means for driving pixels dependent on data to be displayed and with data processing means.

2. A display device as claimed in claim 1, the semiconductor devices being provided with means for recognizing the location of the group of pixels.

3. A display device as claimed in claim 1, wherein the data processing means have a decoding function.

4. A display device as claimed in claim 1, wherein the addressing rate of the semiconductor devices is variable.

5. A display device as claimed in claim 1, wherein the driving means for different part of the displays have separate control means for varying the addressing rate of the associated semiconductor devices.

6. A display device as claimed in claim 1, wherein further driving means comprise a frame memory and means to detect changes between the contents of subsequent frames.

7. A display device as claimed in claim 1, wherein the driving means comprise a frame memory and means to detect changes between the contents of subsequent frames.

8. A display device as claimed in claim 1, wherein encoded data to be displayed is transported to at least a group of the semiconductor devices after detecting a certain amount of change between the contents of subsequent frames or of subsequent subframes.

9. A display device as claimed in claim 1 wherein encoded data to be displayed is transported to at least a part of the group of the semiconductor devices at full frame rate

10. A display device as claimed in claim 9 wherein at least a part of the group of the semiconductor devices receives the most significant part of the data to be displayed.

11. A display device as claimed in claim 10 wherein at least a part of the group of the semiconductor devices receives refinement data of the data to be displayed.

12. A display device as claimed in claim 1, wherein further driving means for the display comprise an encoding function.

13. A display device as claimed in claim 2, wherein the means for recognizing the location have a read-only structure.

14. A display device as claimed in claim 2, wherein the means for recognizing the location comprise a programmable memory.

15. A display device as claimed in claim 1, wherein the drive means have a bus structure.
